(19) United States
(12) Patent Application Publication
(10) Pub. No.: US 2003/0173650 A1
(43) Pub. Date: Sep. 18, 2003

(54) Micro channel in a substrate

(76) Inventors: Olle Larsson, Stockholm (SE); Anna-Lisa Tiensuu, Uppsala (SE)

Correspondence Address: FULBRIGHT & JAWORSKI, LLP, 1301 MCKINNEY, SUITE 5100, HOUSTON, TX, 77010-3095, US

(21) Appl. No.: 10/276,282

(22) PCT Filed: May 11, 2001
(86) PCT No.: PCT/SE01/01031

(30) Foreign Application Priority Data
May 12, 2000 (SE) 0001790-5

(51) Int. Cl. H01L 29/06

(52) U.S. Cl. 257/622

(57) ABSTRACT

The present invention relates to micro channels (1) in a substrate (5) wherein said micro channels has an internal surface (7, 9, 11) that in a region (15), adapted for distributing fluid, has one or more grooves (17, 27, 37, 47, 57, 77) and/or one or more abutting projections (59, 69, 79) which extend at least partly from the bottom of the micro channel to the top of the micro channel.

### TECHNICAL FIELD OF THE INVENTION

The present invention relates to a method for providing surface coatings, for example hydrophobic barriers, in a micro channel. The invention also relates to a device comprising the micro channel to be provided with the surface coating and to the use of the micro channel and of the device after they have been subjected to the inventive method.

### DESCRIPTION OF RELATED ART

It is useful to provide locally modified areas on a surface in microfluidic devices in order to control the flow of fluids, in particular liquids, in such devices or to attract certain reagents or to act as a primer for further processing. For example, it is often useful to provide a micro channel with a hydrophobic coating, which covers all or part of the inner surface of the micro channel. This hydrophobic coating prevents a polar fluid from proceeding along the microchannel unless the fluid is driven by a force that can overcome the blockage caused by the hydrophobic coating. Such a force can be provided by spinning the device containing the micro channel (centripetal force/action) or pressurising the fluid. The hydrophobic coating acts as a passive valve or barrier.

Components that are used to modify surfaces are often dissolved in a solvent to facilitate application of the components to the surface. A hydrophobic component, for instance, is often dissolved in a solvent to lower its viscosity and then sprayed (for example by airbrush through a mask) or painted onto the part of the micro channel, which is to be modified. A problem that often occurs when applying this kind of solutions is that due to their wetting properties the solutions do not cover satisfactorily the vertical walls of the micro channel but run down to the bottom of the micro channel and become distributed along the bottom edges of the channel. This increase the risk for unsatisfactory operation of modified surfaces, e.g. as hydrophobic valves when hydrophobic components have been applied.

In order to simplify the understanding of the present invention, a frame of reference will be defined in which the base (bottom) of the micro channel is considered to extend in a horizontal direction and the side walls to extend up from the base in a vertical direction. This in particular applies to the drawings and the corresponding text. This is not intended to imply any limitation to the present invention, the use of which is not affected by how the walls and base (bottom) are orientated. Once the open side of a micro channel has been covered, the direction-oriented terms “side”, “bottom” and “top” become redundant.

### SUMMARY

The object of the invention is to solve the above stated problems.

The present invention solves the above stated problems by modifying a surface in a micro channel of a device, which surface has the features mentioned in the characterising part of claim 1. This kind of microchannel and/or device is novel and defines the first embodiment of the invention. The method used defines the second embodiment. It solves the above-mentioned problems and has the features mentioned in the characterising part of claims 4 and 5. Other features of both embodiments are as defined in the sub claims and elsewhere in this text.

The first embodiment is a micro channel fabricated in a substrate. The characteristic feature of the internal surface of the micro channel is that it comprises a surface region where there is one or more grooves and/or one or more abutting projections which extend in a wall at least partly from one side of the micro channel to the opposite side, e.g. at least partly from the bottom of the micro channel to the top of the micro channel or vice versa. In sub aspects of this embodiment, the groves and projections may exhibit surface properties that are obtainable by treatment according the second embodiment of he invention. In a further sub aspect the micro channel is covered as described below, i.e. have walls in all directions except for inlet and outlet openings, and other openings that provide desired functionalities, e.g. air vents.

The second embodiment is a method for locally modifying a part of the internal surface of a micro channel fabricated in a substrate. The method is characterized by comprising the steps of:

(i) providing a micro channel which is manufactured in a substrate and in which a part of the internal surface has one or more grooves and/or one or more abutting projections which extend at least partly from one side of the micro channel to the opposite side, for instance at least partly from the bottom of the micro channel to the top of the microchannel or vice versa; and

(ii) applying a fluid, i.e. a liquid, comprising a component that is capable of modifying said part of the surface to (a) the bottom of said groove or grooves and/or (b) the junction(s) between said projection or projections and the remaining part of said internal surface.

Step (ii) (b) means that the liquid can be applied to the junction between two projections bases of which are connected edge to edge or to the junction between the base of one projection and the remaining part of the internal surface.

After volatile components of the applied fluid have been evaporated, possibly followed by one or more post-treatments of the modified surface or of other internal part surfaces of the micro channel, the micro channel can be used as defined below for the third embodiment of the invention. One particular post-treatment procedure is to apply a cover, for instance in the form of a lid, on top of the micro channel (if the micro channel has one open side).

Various printing and/or stamping and/or spraying techniques etc may be used for applying the fluid in step (ii) above. The equipment selected should ensure proper adherence and coverage of the modifying component to the surface. Examples of useful printing techniques are those that utilize a printer head for the application of drops of liquids, such as in various ink-jet or spray techniques, and of powders, such as in various laser techniques.

It has been found that printing and stamping techniques with particular emphasis of ink-jet techniques can be used to locally modify internal surfaces in micro channels irrespective of the presence or absence of irregularities, such as grooves or projections. Accordingly the inventive concept presented herein also encompasses the general use of these kinds of printing techniques for local modification of the kind of surfaces mentioned in this paragraph. In the method and device in accordance with the present invention, portions of a micro channel which are intended to have a modified surface are provided with one or more grooves and/or one or more abutting projections which extend at least partly from the base of each wall to the top of the wall. The groove(s) and/or projections ensure that when a suitable quantity of surface modifying liquid is applied to the groove(s) and/or projections, capillary attraction causes the liquid to wet substantially the whole length of the groove(s) and/or join between the projections and/or between a projection and the remaining part of the internal surface thereby ensuring that when the surface modifying liquid dries it leaves a modified surface which extends substantially from the base of each wall to its top, i.e. the modified surface will be in form of a continuous line of from one wall to an opposite wall. This kind of irregularities in the interior surface will thus improve the distribution of a fluid, i.e. a liquid that is applied in order to locally modify the surface of the micro channel.

A third embodiment of the invention means that a liquid flow is allowed to pass through a covered form of the micro channel as defined or obtained in the first and second aspect of the invention. This embodiment thus comprises the steps of: (i) providing a device in form of a micro channel as defined for the first aspect or obtained as defined for the second aspect, and (ii) applying a liquid flow through the micro channel, and (iii) possibly halting the front of a liquid at the grooves and/or projections defined in the first aspect of the invention. The force applied to drive the flow determines if the front of the liquid shall pass the channel part containing the surface irregularities (groves and/or projections). The term “front” includes the borderline between two different liquids, for instance between two unmixed liquids such as between two immiscible liquids, or between a liquid and gas (air). It follows that the liquid flow may comprise a sequence of liquid zones that are different with respect to liquid constituents. The liquid zones may be physically separated by gas (air) zones.

In one particular type of third embodiment variants, one utilizes a micro channel structure in which the surface modification in the grooves and/or in a joint between two projections and/or between a projection and a remaining internal surface are hydrophobic surface breaks. In this kind of micro channels the driving force for a liquid flow in form of an aqueous solution can be adapted such that a liquid front will stop at the irregularities and pass through by increasing the driving force.

In a micro channel either or both of the width or depth at the position where the above-mentioned irregularities in the internal walls are present are ≦500 μm, such as ≦100 μm or ≦50 μm or ≦10 μm. Typically the micro channels are covered and capable of retaining liquid, for instance by capillary forces.

The invention will be described more closely in the following by means of non-limiting examples of embodiments and with figures.

### BRIEF DESCRIPTION OF THE DRAWING

FIG. 1 is a plan view of one embodiment of a device in accordance with the present invention.

FIG. 2 is a lateral cross-sectional view through line II-II in FIG. 1.

FIG. 3 is a plan view of a second embodiment of a device in accordance with the present invention.

FIG. 4 is a lateral section through line IV-IV in FIG. 3.

FIGS. 5a-g show several different possible arrangements of grooves and projections in accordance with the present invention.

### DETAILED DESCRIPTION OF EMBODIMENTS

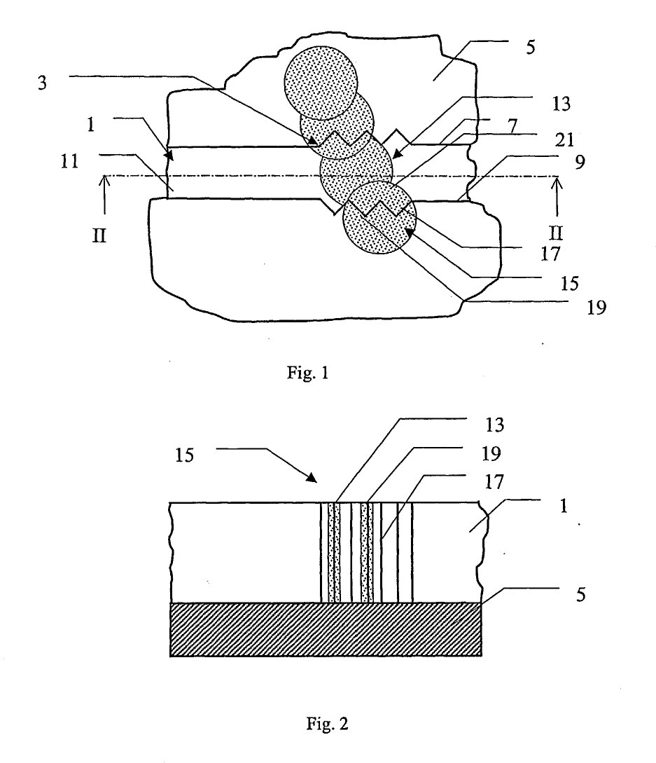

FIGS. 1 and 2 show, respectively, schematically a plan view from above and a cross-sectional view, of a portion of one embodiment of a micro channel 1 provided with an arrangement 3, in accordance with the present invention, for improving the distribution of a surface modifying coating. Micro channel 1 is formed in any suitable way, for example injection moulding, in a substrate 5, which substrate 5 is preferably made of a polymer material such as polycarbonate plastic. Micro channel 1 has an internal surface comprised of substantially vertically extending sidewalls 7, 9 and a substantially horizontal base 11, which connects the sidewalls 7,9. In this example the micro channel has a quadratic cross-section but other cross-section shapes such as triangular, semicircular, trapezoidal or the like are also possible. In this example of an embodiment of the present invention, it is intended that a region 15 of the micro channel 1 is to act as a hydrophobic valve. The sidewalls 7, 9 in region 15 are provided with an arrangement 3 in the form of grooves 17, which are intended to receive a hydrophobic coating 13. In this embodiment the grooves 17 have a V-shaped cross-section and extend from the base of the sidewalls 7, 9 to the tops of the sidewalls 7,9. The hydrophobic coating 13 can be dissolved in a solvent and applied to the region 15 in the form of droplets 21 by a computer controlled printer head, such as an ink-jet printer head. A pattern of preferably overlapping droplets is emitted by the ink-jet printer head towards the region 15 (as shown by shaded circles (not drawn to scale) in FIG. 1 and any droplets 21 which touch the grooves 17 will tend to flow up the base 19 of the V of the groove 17 due to surface forces. If the total volume of the droplets which touch a groove is sufficiently large then the whole of the base of the V of the groove 17 will be filled with the hydrophobic solution and when the solvent evaporates a continuous line of hydrophobic material which extends from the base of the groove 17 to the top of the groove 17 will be left in the groove, as shown by shading in FIG. 2.

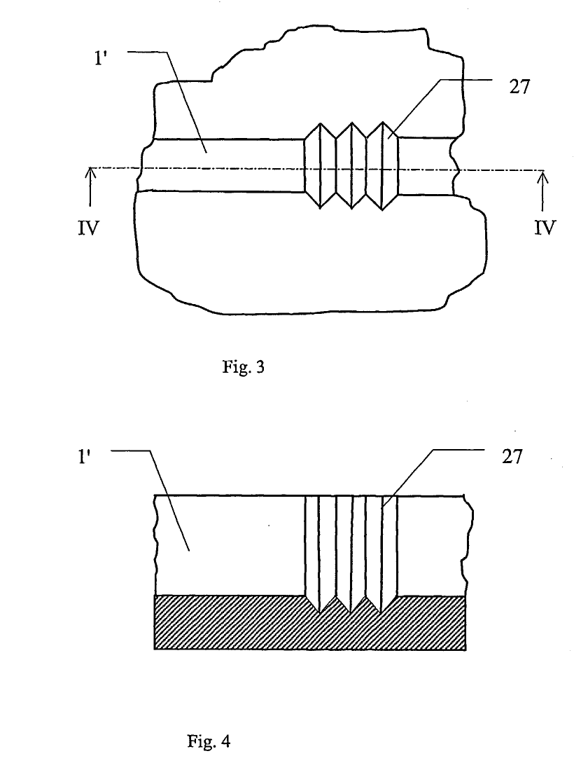

In another embodiment of the invention shown in FIGS. 3 and 4, grooves 27 also extend across the base 11 of the microchannel 1′.

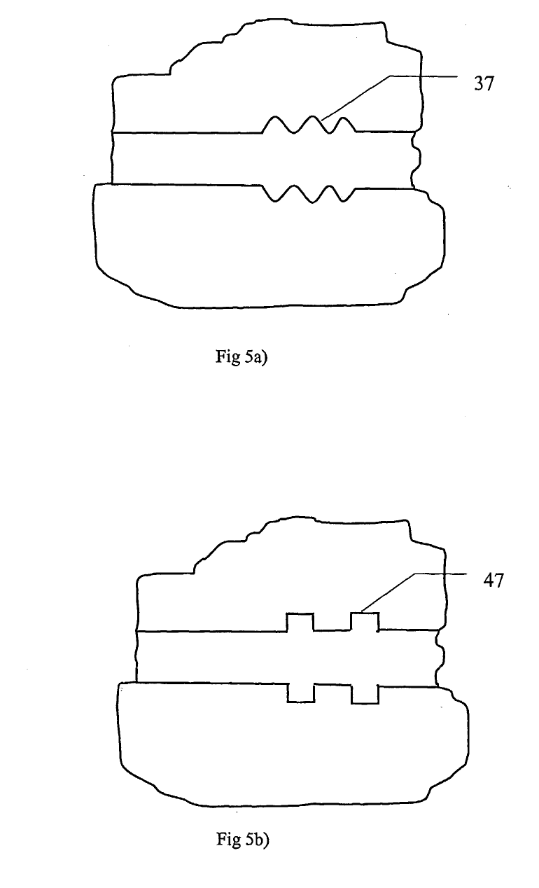

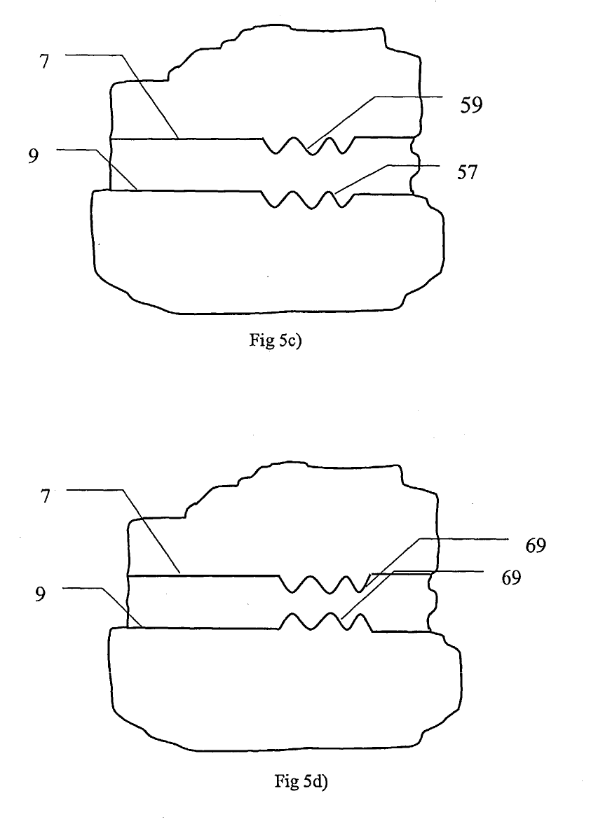

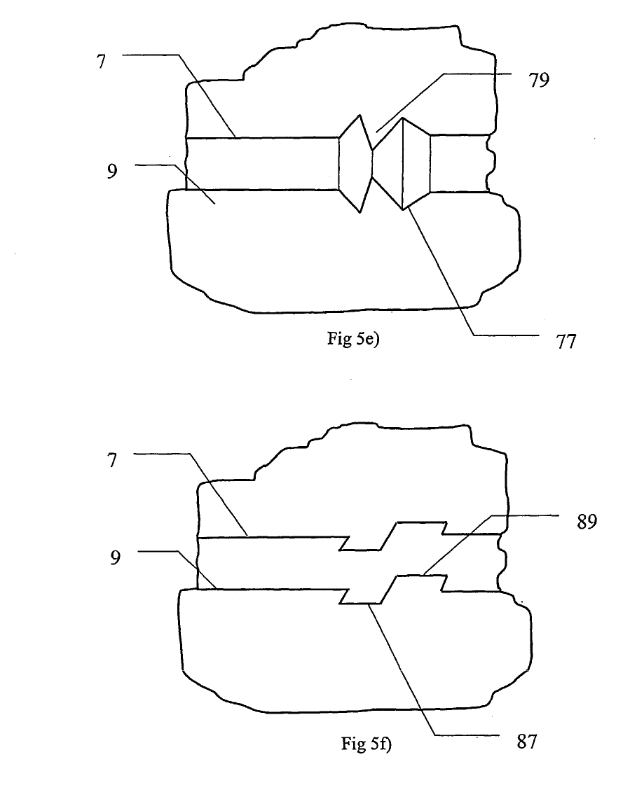

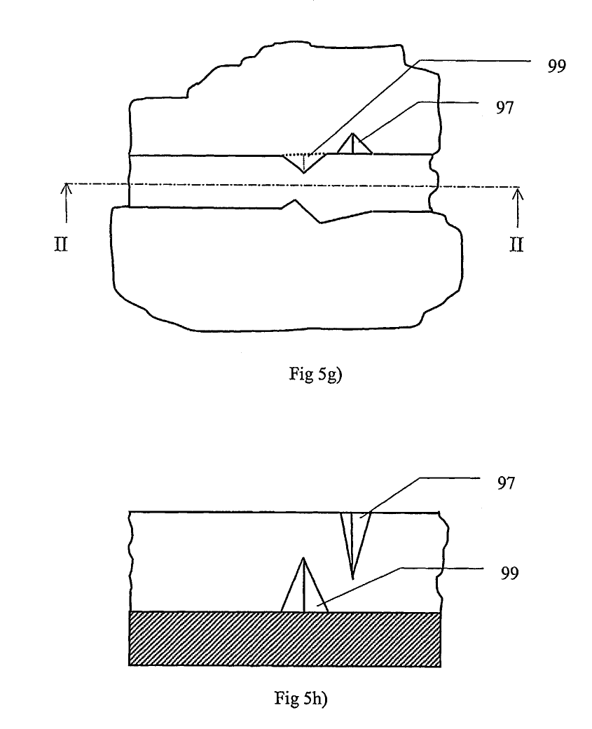

In a further embodiment shown in FIG. 5a, grooves 37 have corrugated cross-sections.

In yet a further embodiment shown in FIG. 5b, there are grooves 47 having quadratic cross-sections.

In another further embodiment shown in FIG. 5c, sidewall 7 is provided with projections 59 having a corrugated cross-section while sidewall 9 is provided with grooves 57 have corrugated cross-sections. In this embodiment the projections 59 and grooves 57 have complementary shapes and are so positioned that in the length of micro channel encompassing the grooves 57 and projections 59, the width of the micro channel between the grooves 57 and projections 59 is substantially constant. Any droplets of surface modifying fluid, which touch the junction of the bases of the projection(s) and the sidewall, will tend to flow up this junction.

In a further embodiment shown in FIG. 5d, sidewalls 7, 9 are provided with projections 69 having a corrugated cross-section. In this embodiment the projections 69 are so positioned that the width of the micro channel varies between a minimum value where the peaks of projections 69 in the respective sidewalls 7, 9 are opposite each other, to a maximum value where troughs between projections 69 are opposite each other.

In a further embodiment shown in FIG. 5e, sidewalls 7, 9 are provided with alternating grooves 77 and projections 79 with triangular cross-sectional profiles.

In a further embodiment shown in FIG. 5f, sidewalls 7, 9 are provided with alternating grooves 87 and projections 89 with trapezoidal cross-sectional profiles.

FIG. 5g and the corresponding section in FIG. 5h show embodiments of grooves 97 and projections 99 that do not have a constant cross-section throughout their lengths.

The sizes of the grooves and/or projections preferably do not exceed more than 40% of the width/diameter of the micro channel and most preferably lie in the range of between 5% and 20% of the width/diameter of the micro channel.

The internal angle of the troughs of the grooves can be any angle that is less than 180° and preferably, for ease of manufacturing, should be between 20° and 160°. The angle that the base of the projections make with the sidewall of the micro channel can also be any angle that is less than 180° and preferably, for ease of manufacturing, should be between 90° and 160°.

Although not shown in the figures, it is of course possible to provide all the embodiments of the invention with grooves or projections in the horizontal base of the micro channel. Although the invention has been illustrated by means of examples with substantially vertical, straight sidewalls and a horizontal, straight base, it is of course possible that the sidewalls are inclined to the vertical and/or are curved and/or that the base is curved and/or sloping. Additionally, it is also conceivable that the micro channel has a triangular cross-section formed by just two sidewalls the intersection of which forms the base of the micro channel. Furthermore, if the micro channel is provided with a cover in order to form a closed channel, then it is possible to provide the surface of the cover that faces into the micro channel with similar grooves and/or projections.

While the invention has been illustrated by examples in which the grooves and projections extend all the way up the sidewalls of the micro channel, it is also conceivable that the grooves and/or projections just extend partly up the sidewalls. Preferably, the grooves and projections extend over at least 50% of the height of the sidewalls.

Furthermore it is conceivable to have grooves or projections which do not extend straight up from the base of a sidewall to its top but which instead are inclined in the longitudinal direction of the micro channel.

1. Micro channel (1) in a substrate (5) wherein said micro channel comprises an internal surface (7, 9, 11) characterised in that said micro channel comprises a region (15) where said internal surface (7, 9, 11) has one or more grooves (17, 27,37, 47, 57, 77, 87, 97) and/or one or more abutting projections (59, 69, 79, 89, 99) which extend at least partly from the bottom of the micro channel to the top of the micro channel.

2. Micro channel in accordance with claim 1 characterised in that said micro channel has a base (11) connecting the base of a first sidewall (7) with the base of a second sidewall (9).

3. Micro channel in accordance with claim 2 characterised in that in said region (15), said base (11) has one or more grooves (17, 27,37, 47, 57, 77, 87, 97) and/or one or more abutting projections (59, 69, 79, 89, 99) which extend at least partly from the base of each sidewall (7) towards the base of the opposite sidewall (9).

4. Method of applying a fluid to the internal surface of a micro channel characterised by the steps of providing said internal surface (7, 9, 11) with one or more grooves (17, 27,37, 47, 57, 77, 87, 97) and/or one or more abutting projections (59, 69, 79, 89, 99) which extend at least partly from the bottom of said micro channel to the top of said micro channel; and applying said fluid to the bottom of said groove or grooves (17, 27, 37,47,57, 77, 87, 97) or to the junction(s) between said projection or projections and said internal surface (7, 9, 11).

5. Method in accordance with claim 4 characterised in that said fluid is applied by being ejected from a printer head.
